(19) United States
(12) Patent Application Publication
(10) Pub. No.: US 2022/0052087 A1
(43) Pub. Date: Feb. 17, 2022

(54) IMAGE SENSOR CHIP, MANUFACTURING METHOD, IMAGER SENSOR, AND PHOTOGRAPHING DEVICE

(71) Applicant: SZ DJI TECHNOLOGY CO., LTD., Shenzhen (CN)

(72) Inventors: Ze XU, Shenzhen (CN); Shiwu ZHAN, Shenzhen (CN)

(21) Appl. No.: 17/512,373

(22) Filed: Oct. 27, 2021

Related U.S. Application Data
(63) Continuation of application No. PCT/CN2019/084714, filed on Apr. 28, 2019.

(51) Int. Cl. H01L 27/146

(52) U.S. Cl. CPC H01L 27/14605; H01L 27/14643; H01L 27/1461; H01L 27/14689; H01L 27/1469

(57) ABSTRACT

An image sensor chip includes a structural layer member including a plurality of structural layers. Each of the plurality of structural layers is distributed in a photosensitive circuit area and a peripheral reading circuit area of the image sensor chip. A first part and a second part of one structural layer in the structural layer member include insulation materials with different characteristic properties. The first part is a part of the one structural layer in the photosensitive circuit area, and the second part is a part of the one structural layer in the peripheral reading circuit area.

### CROSS-REFERENCE TO RELATED APPLICATION

This application is a continuation of International Application No. PCT/CN2019/084714, filed Apr. 28, 2019, the entire content of which is incorporated herein by reference.

### TECHNICAL FIELD

The present disclosure relates to the technical field of image sensor and, more particularly, to an image sensor chip, a manufacturing method, an image sensor, and a photographing device.

### BACKGROUND

In a fabrication process of an image sensor chip, metal wires or functional elements are insulated by using insulation materials to avoid mutual interference.

In related technologies, since a peripheral reading circuit area and a photosensitive circuit area of an image sensor chip both include the same insulation material and are integrally fabricated, the peripheral reading circuit area and the photosensitive circuit area will be restricted in optimized design of different performances.

### SUMMARY

In accordance with the disclosure, there is provided an image sensor chip including a structural layer member including a plurality of structural layers. Each of the plurality of structural layers is distributed in a photosensitive circuit area and a peripheral reading circuit area of the image sensor chip. A first part and a second part of one structural layer in the structural layer member include insulation materials with different characteristic properties. The first part is a part of the one structural layer in the photosensitive circuit area, and the second part is a part of the one structural layer in the peripheral reading circuit area.

Also in accordance with the disclosure, there is provided a manufacturing method of an image sensor chip including sequentially forming a plurality of structural layers of a structural layer member. Each of the plurality of layers is distributed in a photosensitive circuit area and a peripheral reading circuit area of the image sensor chip. Forming one structural layer of the plurality of structural layers includes forming a first part and a second part of the one structural layer using insulation materials with different characteristic properties. The first part is a part of the one structural layer in the photosensitive circuit area, and the second part is a part of the one structural layer in the peripheral reading circuit area.

### BRIEF DESCRIPTION OF THE DRAWINGS

In order to explain the technical solutions in the embodiments of the present disclosure more clearly, reference is made to the accompanying drawings, which are used in the description of the embodiments. Obviously, the drawings in the following description are only some embodiments of the present disclosure, and other drawings can be obtained from these drawings without any inventive effort for those of ordinary skill in the art.

FIG. 1 is a schematic structural diagram of an image sensor chip.

FIG. 2 is a schematic cross-sectional view of an image sensor chip.

FIG. 3 is a schematic cross-sectional view of an image sensor chip according to an embodiment of the present disclosure.

FIG. 4 is a schematic diagram of a fabrication process of a first structural layer in image sensor chip processing according to an embodiment of the present disclosure.

FIG. 5 is a schematic diagram showing a base layer before deposition in image sensor chip processing according to an embodiment of the present disclosure.

FIG. 6 is a schematic diagram showing a structural layer after a first deposition in image sensor chip processing according to an embodiment of the present disclosure.

FIG. 7 is a schematic diagram showing a structural layer after etching in image sensor chip processing according to an embodiment of the present disclosure.

FIG. 8 is a schematic diagram showing a structural layer after a second deposition in image sensor chip process according to an embodiment of the present disclosure.

FIG. 9 is a schematic structural diagram of an image sensor according to an embodiment of the present disclosure.

### DETAILED DESCRIPTION OF THE EMBODIMENTS

The technical solutions in the embodiments of the present disclosure will be described in detail with reference to the accompanying drawings. Obviously, the described embodiments are only some of rather than all the embodiments of the present disclosure. Based on the described embodiments, all other embodiments obtained by those of ordinary skill in the art without inventive effort shall fall within the scope of the present disclosure.

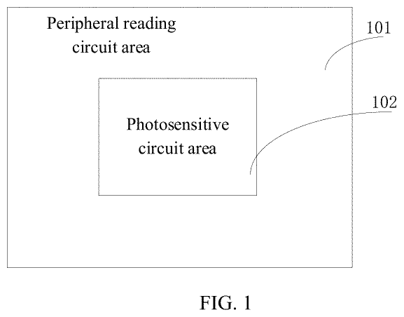

FIG. 1 is a schematic structural diagram of an image sensor chip. As shown in FIG. 1, the image sensor chip includes a peripheral reading circuit area 101 and a photosensitive circuit area 102. The photosensitive circuit area 102 is located in the middle of the image sensor chip, and the peripheral reading circuit area 101 is located around the photosensitive circuit area 102.

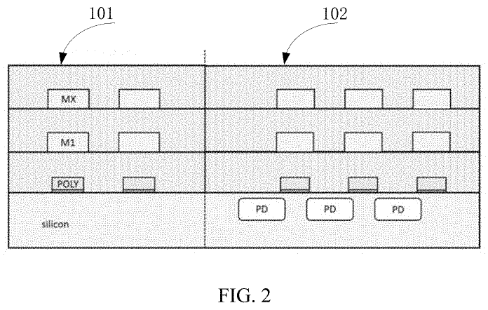

Referring to FIG. 2, the image sensor chip includes a structural layer member, and the structural layer member includes a plurality of structural layers. Each structural layer is distributed in the photosensitive circuit area 101 and the peripheral reading circuit area 102, and an insulation material needs to be arranged at each structural layer in order to achieve electrical insulation among different members in each structural layer.

Parts of a structural layers in the photosensitive circuit area and in the peripheral reading circuit area can use the same insulation material. Since the photosensitive circuit area is distributed with pixel circuits, and the peripheral reading circuit area is distributed with peripheral reading circuits, requirements for some performance parameters of the two are different. For example, in the photosensitive circuit area, in order to achieve better imaging quality, parasitic capacitance of the pixel circuit needs to be as small as possible to increase charge-to-voltage gain. As such, when the parts of the various structural layers in the photosensitive circuit area and in the peripheral reading circuit area all use the same insulation material, there will be certain restriction in different optimization designs of some parameter performances of the photosensitive circuit area and the peripheral reading circuit area.

Embodiments of the present disclosure provide an image sensor chip, a manufacturing method, an image sensor, and a photographing device.

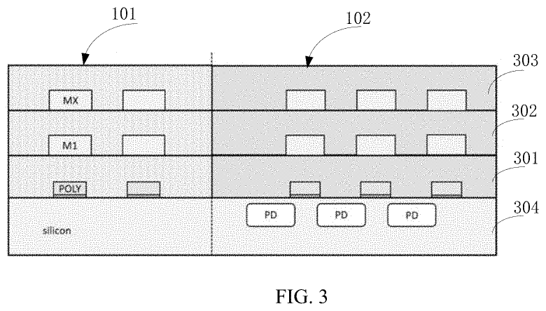

FIG. 3 is a partial cross-sectional view of an image sensor chip according to an embodiment of the present disclosure. As shown in FIG. 3, the image sensor chip provided by the present disclosure is provided with the photosensitive circuit area 102 and the peripheral reading circuit area 101. The image sensor chip includes a structural layer member, and the structural layer member includes a plurality of structural layers. Each structural layer can be distributed in the photosensitive circuit area and the peripheral reading circuit area, i.e., part of a structural layer can be in the photosensitive circuit area and part of the structural layer can be in the peripheral reading circuit area. A first part and a second part of at least one structural layer in the structural layer member can include insulation materials with different characteristic properties. The first part can be a part of the structural layer in the photosensitive circuit area, and the second part can be a part of the structural layer in the peripheral reading circuit area.

In the image sensor chip provided by the present disclosure, the first part and the second part of at least one structural layer in the structural layer member include insulation materials with different characteristic properties, which may be, for example, dielectric constant, density, dimensional stability, etc. As such, the part of the structural layer in the photosensitive circuit area and the part of the structural layer in the peripheral reading circuit area can be designed to have different performance parameters, such as parasitic capacitance, deformation, etc.

In some embodiments, the characteristic property of the insulation material used in the first part is smaller than the characteristic property of the insulation material used in the second part.

In some embodiments, the characteristic property described above is the dielectric constant.

When the characteristic property described above is the dielectric constant, there is at least one structural layer in the structural layer member of the image sensor chip provided by the present disclosure where the dielectric constant of the insulation material used in the part in the photosensitive circuit area is smaller than the dielectric constant of the insulation material used in the part in the peripheral reading circuit area. As such, the pixel circuit in the photosensitive circuit area can have a smaller parasitic capacitance, which increases the charge-to-voltage gain and improves signal-to-noise ratio.

In some embodiments of the present disclosure, the image sensor chip described above can also include a base layer located below the structural layer member, and the first part and the second part of the structural layer in the structural layer member adjacent to the base layer can include insulation materials with different characteristic properties.

Since the base layer has a certain influence on performance of adjacent structural layer, and degree of the influence allowed by the first part and the second part of the structural layer can be different, it may be needed to be so designed that the first part and the second part of the structural layer in the structural layer member adjacent to the base layer include insulation materials with different characteristic properties.

Referring to FIG. 3 again, the image sensor chip provided by the present disclosure includes a base layer 304 and the structural layer member, and the base layer 304 is located below the structural layer member. In some embodiments, the structural layer member includes three structural layers, namely, a first structural layer 301, a second structural layer 302, and a third structural layer 303. For each of the first structural layer 301, the second structural layer 302, and the third structural layer 303, the dielectric constant of the insulation material used in the part in the photosensitive circuit area 102 is smaller than the dielectric constant of the insulation material used in the part in the peripheral reading circuit area 101. In some embodiments, the first structural layer includes a polysilicon gate POLY, the second structural layer includes a metal layer Ml, and the third structural layer includes a metal layer MX. The base layer described above may be a silicon base layer, and the silicon base layer includes a photodiode PD.

In some embodiments, in each structural layer, the dielectric constant of the insulation material used in the part in the photosensitive circuit area is set to be smaller than the dielectric constant of the insulation material used in the part in the peripheral reading circuit area, so that the parasitic capacitance inside the pixel circuit in the photosensitive circuit area and that between the photosensitive circuit area of the structural layer adjacent to the base layer and the base layer are smaller, which increases the charge-to-voltage gain of the pixel circuit and improves the signal-to-noise ratio.

In some embodiments, the insulation material used in the first part includes a mixture of a plurality of insulation materials with characteristic properties.

The insulation materials described above may be silicon oxide, silicon nitride, silicon oxynitride, or silicon carbide.

For example, the mixture may be formed by stirring and mixing.

In some embodiments, the insulation material used in the first part includes a composite formed by stacking a plurality of insulation materials with characteristic properties, and the insulation materials may be silicon oxide, silicon nitride, silicon oxynitride, or silicon carbide.

For example, a manner of stacking includes depositing a layer of insulation material B over a layer of insulation material A to form a composite formed by stacking the insulation material A and insulation material B. In some embodiments, the composite may also be formed by stacking two or more insulation materials with different characteristic properties.

The insulation material used in the second part can be a semiconductor standard dielectric material, and the insulation material used in the second part can also be one insulation material, a mixture of a plurality of insulation materials, or a composite formed by stacking a plurality of insulation materials.

In some embodiments of the present disclosure, the image sensor chip described above is a complementary metal-oxide-semiconductor (CMOS) chip.

Compared with a CMOS chip in the existing technologies, the CMOS chip consistent with the disclosure can have a smaller parasitic capacitance in the photosensitive circuit area, so that the charge-to-voltage gain is higher, the signal-to-noise ratio is improved, and performance is improved.

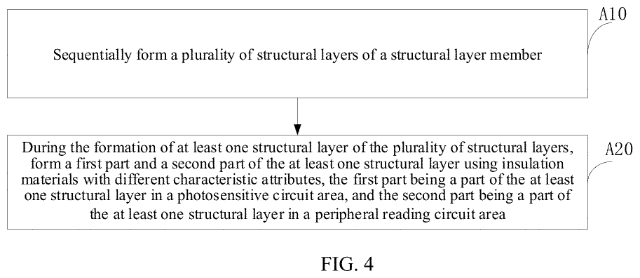

FIG. 4 is a schematic flow chart of a manufacturing method of the above-described sensor chip according to an embodiment of the present disclosure. The image sensor chip is provided with the photosensitive circuit area and the peripheral reading circuit area. The image sensor chip includes the structural layer member, and the structural layer member includes a plurality of structural layers. Each structural layer is distributed in the photosensitive circuit area and the peripheral reading circuit area. Referring to FIG. 4, the method includes the following processes.

A10, sequentially forming the plurality of structural layers in the structural layer member.

The above may be sequentially forming the plurality of structural layers in the structural layer member in a bottom-up order.

A20, during the formation of at least one structural layer of the plurality of structural layers, forming the first part and the second part of the at least one structural layer using insulation materials with different characteristic properties, the first part being the part of the at least one structural layer in the photosensitive circuit area, and the second part being the part of the at least one structural layer in the peripheral reading circuit area.

The above characteristic property can be an property such as density, dielectric constant, dimensional stability, etc. As such, according to the image sensor chip fabricated by the method provided by the present disclosure, there is at least one structural layer in the structural layer member where the characteristic property of the insulation material used in the part in the photosensitive circuit area and the characteristic property of the insulation material used in the part in the peripheral reading circuit are different. Compared with the existing technologies in which the parts of each structural layer of the image sensor chip in the photosensitive circuit area and the peripheral reading circuit area include the same insulation material, performance optimization design of the photosensitive circuit area or the peripheral reading circuit consistent with the disclosure is not restricted by use of the same insulation material.

In some embodiments, in process A20 described above, forming the first part and the second part of the structural layer using insulation materials with different characteristic properties can include depositing a first insulation material in the photosensitive circuit area and the peripheral reading circuit area, and etching away deposited first insulation material in the peripheral reading circuit area to obtain the first part; and depositing a second insulation material in the peripheral reading circuit area to obtain the second part. The characteristic property of the first insulation material is different from the characteristic property of the second insulation material.

In some embodiments, when a structural layer is being formed, the first insulation material is first deposited in the photosensitive circuit area and the peripheral reading circuit area of the layer, and then the deposited first insulation material in the peripheral reading circuit area is etched away to obtain the part of the structural layer in the photosensitive circuit area (the first part).

After the deposited first insulation material in the peripheral reading circuit area is etched away, the second insulation material is deposited in the peripheral reading circuit area to obtain the part of the structural layer in the peripheral reading circuit area (the second part). As such, a structural layer including the first part and the second part is obtained.

In some embodiments, in process A20 described above, forming the first part and the second part of the structural layer using insulation materials with different characteristic properties can include depositing the second insulation material in the photosensitive circuit area and the peripheral reading circuit area, and etching away deposited second insulation material in the photosensitive circuit area to obtain the second part; and depositing the first insulation material in the photosensitive circuit area to obtain the first part. The characteristic property of the first insulation material is different from the characteristic property of the second insulation material.

In some embodiments, when a structural layer is being formed, the second insulation material is first deposited in the photosensitive circuit area and the peripheral reading circuit area, and after deposition is completed, the deposited second insulation material in the photosensitive circuit area is etched away to obtain the part of the structural layer in the peripheral reading circuit area.

After the second insulation material in the photosensitive circuit area is etched away, the first insulation material is deposited in the photosensitive circuit area, and the part of the structural layer in the photosensitive circuit area is formed after the deposition of the first insulation material is completed.

In the foregoing embodiments, after the first part and the second part of the structural layer are finally formed, chemical mechanical polishing can be performed to flatten surface of the structural layer. The chemical mechanical polishing can also be performed after each deposition is completed, or after each deposition and etching, which is not limited in the present disclosure.

In some embodiments, the characteristic property of the first insulation material is smaller than the characteristic property of the second insulation material.

In some embodiments, the characteristic property described above is the dielectric constant.

As such, according to the image sensor chip fabricated by the method provided by the present disclosure, there is at least one structural layer in the structural layer member where the dielectric constant of the insulation material used in the part in the photosensitive circuit area is smaller than the dielectric constant of the insulation material used in the part in the peripheral reading circuit area, so that the image sensor chip can have a smaller parasitic capacitance inside the pixel circuit in the photosensitive circuit area.

In some embodiments of the present disclosure, before sequentially forming the plurality of structural layers in the structural layer member, the method includes first forming the base layer. After the base layer is formed, the first part and the second part of the structural layer adjacent to the base layer are formed using insulation materials with different characteristic properties.

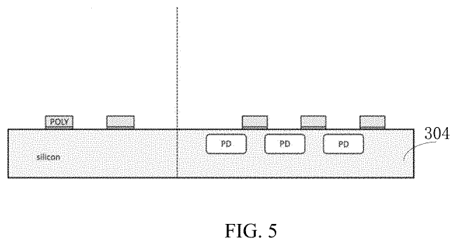

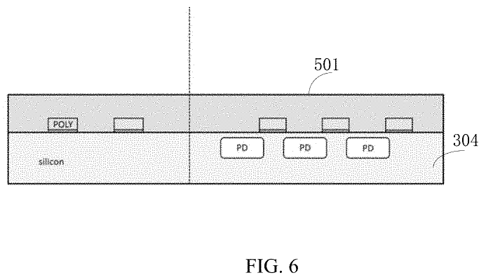

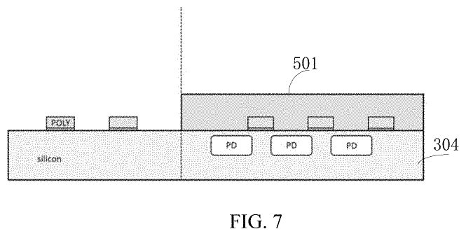

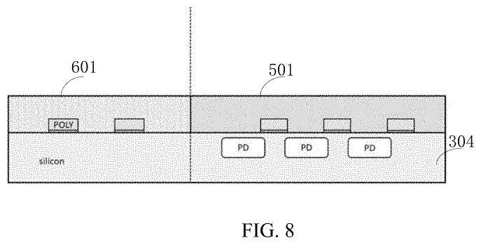

For example, referring to FIGS. 5-8, a polysilicon gate layer is fabricated above the base layer 304 to obtain a structure shown in FIG. 5. The first insulation material is deposited (first deposition) to obtain a structure shown in FIG. 6. The first insulation material in the peripheral reading circuit area is etched away to obtain a structure shown in FIG. 7. At this point, a first part 501 of the structural layer is formed. Then, the second insulation material is deposited in the peripheral reading circuit area (second deposition) to obtain a structure shown in FIG. 8. After the deposition is completed, a second part 601 of the structural layer is obtained. Finally, the chemical mechanical polishing is performed, and the structural layer is fabricated.

As such, in the image sensor chip fabricated according to the manufacturing method provided by the present disclosure, for the structural layer in the structural layer member adjacent to the base layer, the characteristic property of the insulation material used in the part located in the photosensitive circuit area is different from the characteristic property of the insulation material used in the part located in the peripheral reading circuit area.

In some embodiments of the present disclosure, the above-described base layer is located below the plurality of structural layers, and the plurality of structural layers are sequentially stacked and formed above the base layer.

In some embodiments, the insulation material used in the first part includes a mixture of a plurality of insulation materials with characteristic properties, and the insulation material may be silicon oxide, silicon nitride, silicon oxynitride, or silicon carbide.

For example, the mixture may be formed by stirring and mixing.

In some embodiments, the insulation material used in the first part includes a composite formed by stacking a plurality of insulation materials with characteristic properties, and the insulation materials may be silicon oxide, silicon nitride, silicon oxynitride, or silicon carbide.

For example, a manner of stacking includes depositing a layer of insulation material B with different characteristic property from that of insulation material A over a layer of insulation material A to form a composite formed by stacking the insulation material A and insulation material B. In some embodiments, the composite may also be formed by stacking two or more insulation materials with different characteristic properties.

The insulation material used in the second part can be a semiconductor standard dielectric material, and the insulation material used in the second part can also be only one insulation material, a mixture of a plurality of insulation materials, or a composite formed by stacking a plurality of insulation materials.

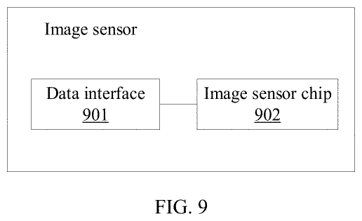

FIG. 9 is a schematic structural diagram of an image sensor according to an embodiment of the present disclosure. As shown in FIG. 9, the image sensor includes a data interface 901 and an image sensor chip 902 consistent with the disclosure, such as any of the example image sensor chips described above, and the data interface 901 is configured to provide data input and/or output for the image sensor chip.

In the image sensor provided by the present disclosure, for the structural layer in the structural layer member of the image sensor chip, the characteristic property of the insulation material used in the photosensitive circuit area is different from the characteristic property of the insulation material used in the peripheral reading circuit area, so that he parasitic capacitance of the image sensor chip in the photosensitive circuit area can be further reduced, which finally causes the image sensor including the image sensor chip to obtain an optical image with better quality.

The present disclosure further provides a photographing device, which includes a lens and an image sensor consistent with the disclosure, such as one of the example image sensors described above, where the lens receives light and transmits the light to the image sensor for imaging.

The photographing device provided by the present disclosure has a positive effect of better imaging quality.

For the device consistent with the present disclosure, since it basically corresponds to the method consistent with the present disclosure, reference may be made to some of the description of the method with the present disclosure. The example device described above is only illustrative. The units described as separate components may or may not be physically separated, and the components displayed as units may or may not be physical units, i.e., they may be located in one place, or distributed on multiple network units. Some or all of the modules may be selected according to actual needs to achieve the objectives of the present disclosure. Those of ordinary skill in the art can understand and implement the present disclosure without inventive effort.

It should be noted that relational terms such as first and second are only used herein to distinguish one entity or operation from another entity or operation, and do not necessarily require or imply any such actual relationship or order between these entities or operations. The terms “include,” “involve” or any other variations thereof are intended to cover non-exclusive inclusion, so that a process, method, object, or device including a series of elements not only includes those elements, but also includes other elements that are not explicitly listed, or also includes elements inherent to such processes, method, object, or device. Without further restrictions, the element associated with phrase “including a . . . ” does not exclude the existence of other identical elements in the process, method, object, or device that includes the element.

The above are detailed description of a method and device provided by the present disclosure. Some examples are used in this specification to illustrate the principles and embodiments of the present disclosure. The description of the embodiments is for the purpose of helping to understand the method of this disclosure and its core idea. For those of ordinary skill in the art, there will be changes in specific embodiments and application scope according to the idea of this disclosure. In summary, the content of this specification should not be understood as a limitation of the present disclosure.

What is claimed is:

1. An image sensor chip comprising:
a structural layer member including a plurality of structural layers, each of the plurality of structural layers being distributed in a photosensitive circuit area and a peripheral reading circuit area of the image sensor chip;
wherein a first part and a second part of one structural layer in the structural layer member include insulation materials with different characteristic properties, the first part being a part of the one structural layer in the photosensitive circuit area, and the second part being a part of the one structural layer in the peripheral reading circuit area.

2. The chip of claim 1, wherein:
the characteristic property of the insulation material used in the first part is smaller than the characteristic property of the insulation material used in the second part; and
the characteristic properties are dielectric constants.

3. The chip of claim 1, further comprising:
a base layer located below the structural layer member;
wherein the one structural layer is one of the plurality of structural layers that is adjacent to the base layer.

4. The chip of claim 1, wherein the insulation material used in the first part includes a mixture of a plurality of insulation materials with different characteristic properties.

5. The chip of claim 1, wherein the insulation material used in the first part includes a composite formed by stacking a plurality of insulation materials with characteristic properties.

6. The chip of claim 1, wherein the insulation material used in the first part includes at least one of silicon oxide, silicon nitride, silicon oxynitride, or silicon carbide.

7. The chip of claim 1, wherein the insulation material used in the second part includes a mixture of a plurality of insulation materials with characteristic properties.

8. The chip of claim 1, wherein the insulation material used in the second part includes a composite formed by stacking a plurality of insulation materials with characteristic properties.

9. The image sensor chip of claim 1, wherein the image sensor chip is a complementary metal-oxide-semiconductor (CMOS) chip.

10. A manufacturing method of an image sensor chip comprising:
sequentially forming a plurality of structural layers of a structural layer member, each of the plurality of layers being distributed in a photosensitive circuit area and a peripheral reading circuit area of the image sensor chip;
wherein forming one structural layer of the plurality of structural layers includes forming a first part and a second part of the one structural layer using insulation materials with different characteristic properties, the first part being a part of the one structural layer in the photosensitive circuit area, and the second part being a part of the one structural layer in the peripheral reading circuit area.

11. The method of claim 10, wherein forming the first part and the second part of the one structural layer using the insulation materials with different characteristic properties includes:
depositing a first insulation material in the photosensitive circuit area and the peripheral reading circuit area, and etching away a portion of the first insulation material in the peripheral reading circuit area to obtain the first part; and
depositing a second insulation material in the peripheral reading circuit area to obtain the second part, a characteristic property of the first insulation material being different from a characteristic property of the second insulation material.

12. The method of claim 10, wherein forming the first part and the second part of the one structural layer using the insulation materials with different characteristic properties includes:
depositing a second insulation material in the photosensitive circuit area and the peripheral reading circuit area, and etching away a portion of the second insulation material in the photosensitive circuit area to obtain the second part; and
depositing a first insulation material in the photosensitive circuit area to obtain the first part, a characteristic property of the first insulation material being different from a characteristic property of the second insulation material.

13. The method of claim 12, wherein the characteristic property of the first insulation material is smaller than the characteristic property of the second insulation material.

14. The method of claim 10, wherein the characteristic properties are dielectric constants.

15. The method of claim 10, further comprising, before sequentially forming the plurality of structural layers:
forming a base layer;
wherein:
forming the one structural layer includes forming the one structural layer adjacent to the base layer; and
the base layer is located below the plurality of structural layers, the plurality of structural layers being sequentially stacked and formed over the base layer.

16. The method of claim 10, wherein the insulation material used in the first part includes a mixture of a plurality of insulation materials with characteristic properties.

17. The method of claim 10, wherein the insulation material used in the first part includes a composite formed by stacking a plurality of insulation materials with characteristic properties.

18. The method of claim 10, wherein the insulation material used in the first part includes at least one of silicon oxide, silicon nitride, silicon oxynitride, or silicon carbide.

19. The method of claim 10, wherein the insulation material used in the second part includes a mixture of a plurality of insulation materials with characteristic properties.

20. The method of claim 10, wherein the insulation material used in the second part includes a composite formed by stacking a plurality of insulation materials with characteristic properties.
